(19) United States
(12) Patent Application Publication
(10) Pub. No.: US 2014/0232480 A1
(43) Pub. Date: Aug. 21, 2014

(54) CLOCK APPARATUS

(71) Applicant: ISSC TECHNOLOGIES CORP., Hsinchu City (TW)

(72) Inventor: Yi-Lung Chen, Hsinchu City (TW)

(73) Assignee: ISSC TECHNOLOGIES CORP., Hsinchu City (TW)

(21) Appl. No.: 13/769,829

(22) Filed: Feb. 19, 2013

(51) Int. Cl. H03K 3/36

(52) U.S. Cl. CPC H03K 3/36
USPC 331/111

(57) ABSTRACT

The invention provides a clock apparatus includes a clock source, a first resistor, a diode, an amplifier, and an oscillator. The current source provides a current, and the current has a first temperature coefficient. The first resistor has a first end, and the first end receives the current. The anode of the diode is coupled to a second end of the first resistor, the cathode of the diode is coupled to a reference ground. The diode has a second temperature coefficient. The amplifier receives a power source. The amplifier generates an output voltage according to the power source and a voltage on the first end of the first resistor. The oscillator receives the output voltage to be an operating power. Wherein, the first and second temperature coefficients are complementary.

### BACKGROUND OF THE INVENTION

1. Field of Invention

The present invention generally relates to a clock apparatus, and more particularly to the clock apparatus is used to provide a clock signal for a lower power consumption circuit.

2. Description of Prior Art

For nowadays a wireless communication device, standby current is a main factor related to battery life. The lower standby current is, the more working time for the communication device. To keep the communication device in a standby mode, it should have a low power clock to sustain whole system of the communication device. Therefore an oscillator with very low current consumption and stable output frequency is needed and important to whole system of the communication device in the standby mode.

A relaxation oscillator is very suitable for providing a low power clock. Base on RC time constant relaxation and alternate state by the threshold voltage of inverters in the relaxation oscillator, the oscillation frequency of the relaxation oscillator could be well determined. And only the power consumption of inverters should be taken to count, low power purpose could be realized. Besides, a stable operating power is also an important factor to the accuracy of the output frequency.

### SUMMARY OF THE INVENTION

The present invention provides a clock apparatus for providing a clock signal to a lower power consumption circuit.

The present invention provides the clock apparatus includes a current source, a first resistor, a diode, an amplifier, and an oscillator. The current source provides a current, and the current has a first temperature coefficient. The first resistor has a first end, and the first end is coupled to the current source for receiving the current. The diode has an anode and a cathode. The anode is coupled to a second end of the first resistor, the cathode of the diode is coupled to a reference ground. The diode has a second temperature coefficient. The amplifier is coupled to the first end of the first resistor and the amplifier receives a power source. The amplifier generates an output voltage according to the power source and a voltage on the first end of the first resistor. The oscillator is coupled to the amplifier for receiving the output voltage to be an operating power. Wherein, the first and second temperature coefficients are complementary.

Accordingly, the clock apparatus provides a current source with a first coefficient temperature and a diode with a second temperature coefficient, wherein the first and second temperature coefficients are complementary. That is, a voltage level of the output voltage provided by the amplifier is independent to the environment temperature. The output voltage is provided to the oscillator to be the operating power, and a frequency of the clock signal generated by the oscillator is independent to the environment temperature.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a circuit diagram of a clock apparatus 100 according to an embodiment of the present invention.

FIG. 2 is a circuit diagram of a clock apparatus 200 according to the other embodiment of the present invention.

FIG. 3 is a circuit diagram of a clock apparatus 300 according to another embodiment of the present invention.

FIG. 4 is a circuit diagram of the current source ICS in FIGS. 1-3 of the embodiments of the present invention.

### DESCRIPTION OF THE EMBODIMENTS

Reference will now be made in detail to the present preferred embodiment of the invention, examples of which are illustrated in the accompanying drawings.

Wherever possible, the same reference numbers are used in the drawings and the description to refer to the same or like parts.

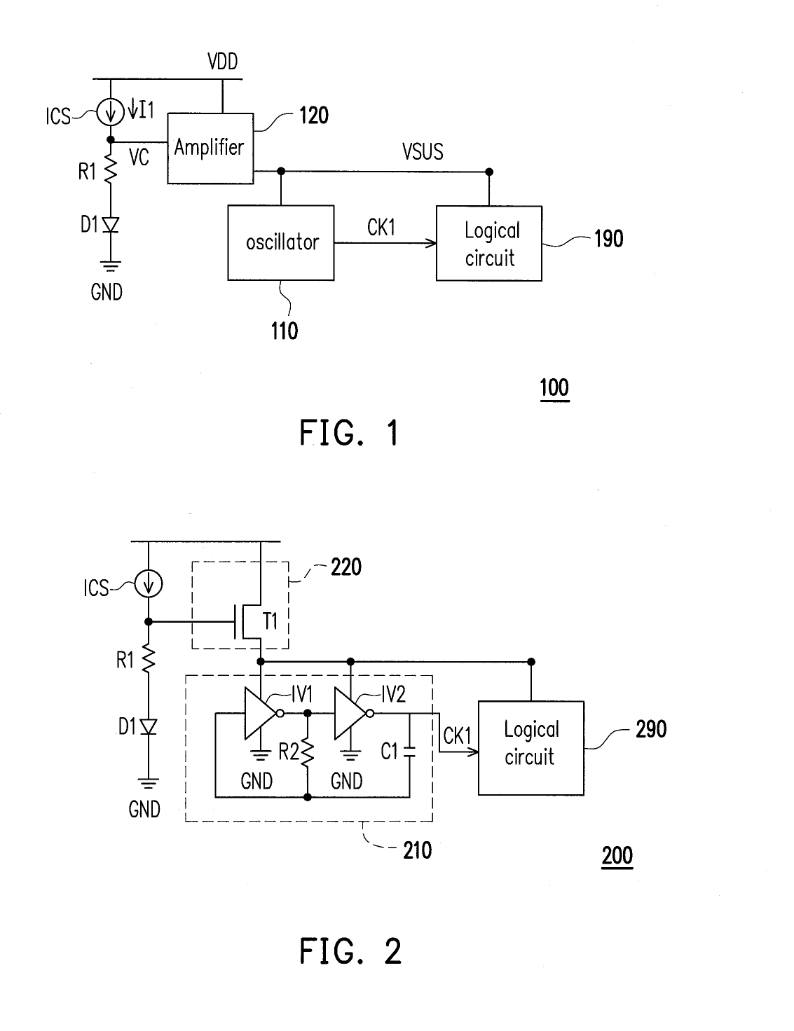

Referring to FIG. 1, FIG. 1 is a circuit diagram of a clock apparatus 100 according to an embodiment of the present invention. The clock apparatus 100 includes a current source ICS, a resistor R1, a diode D1, an amplifier 120 and an oscillator 110. The current source ICS provides a current I1. A first end of the resistor R1 is coupled to the current source ICS for receiving the current I1, that is, the current I1 may flows through the resistor R1. A second end of the resistor R1 is coupled to an anode of the diode D1. A cathode of the diode D1 is coupled to a reference ground GND. In the other word, the current I1 may flow through the diode D1 to the reference ground GND, and the diode D1 is turned on accordingly.

Please notice here, the current I1 has a first temperature coefficient and the diode D1 has a second temperature coefficient, wherein, the first and second temperature coefficients are complementary. That is, a voltage VC on the first end of the resistor R1 may be obtain by the following formula: VC=I1×R1+VD1, wherein, voltage VD1 is a voltage difference between the anode and the cathode of the diode Dl. For example, if the first temperature coefficient is a positive temperature coefficient, and the second temperature coefficient is a negative temperature coefficient. The current I1 is varied in direct proportion to an environment temperature, and the voltage VD1 is varied in an inverse proportion to the environment temperature. That is, the voltage VC on the first end of the resistor R1 may be independent to the environment temperature, and the voltage VC is stable.

The amplifier 120 is coupled to the first end of the resistor R1 for receiving the voltage VC. The amplifier 120 further receives a power source VDD. Furthermore, the amplifier 120 generates an output voltage VSUS according to the power source VDD and the voltage VC on the first end of the resistor R1. Since the voltage VC is stable, the output voltage VSUS generated by the amplifier 120 is independent to the environment.

The oscillator 110 is coupled to the amplifier 120 and a logical circuit 190. The oscillator 110 receives the output voltage VSUS from the amplifier 120. The oscillator 110 may be a relaxation oscillator, and the oscillator 110 receives the output voltage VSUS to be an operating power. Furthermore, the oscillator 110 generates a clock signal CK1, and provides the clock signal CK1 to the logical circuit 190. In this embodiment, the output voltage VSUS is also provided to the logical circuit 190 to be the operating power of the logical circuit 190. The logical circuit 190 may be a circuit worked in a low power consumption mode (such as sleep mode or standby mode).

Referring to FIG. 2, FIG. 2 is a circuit diagram of a clock apparatus 200 according to the other embodiment of the present invention. The clock apparatus 200 includes a current source ICS, a resistor R1, a diode D1, an amplifier 220 and an oscillator 210. The oscillator 210 is used to generate a clock signal CK1 to provide to the logical circuit 290. In the embodiment, the amplifier 220 is a transistor T1. The transistor T1 has a first end, second end and a control end. The first end of the transistor T1 receives the power source VDD, the second end of the transistor T1 generates the output voltage VSUS, and the control end is coupled to the current source ICS and the resistor R1. The transistor T1 may be a MOSFET (metal oxide semiconductor field-effect transistor). The control end of the transistor T1 may be a gate of the transistor T1, the first and second ends may be a source and drain of the transistor T1, respectively.

The oscillator 210 includes inverters IV1 and IV2, resistor R2 and capacitor C1. An output end of the inverter IV1 is coupled to an input end of the inverter IV2. The resistor R2 is coupled between the output end of the inverter IV1 and an input end of the inverter IV1. The capacitor C1 is coupled between the output end of the inverter IV2 and the input end of the inverter IV1. The inverters IV1 and IV2 receives the output voltage VSUS from amplifier 220. The output voltage VSUS is used to be the operating power of the inverters IV1 and IV2.

In this embodiment, the voltage VC on a connection end of the resistor R1 and the current source ICS may be presented as follow formula: VC=I1×R1+VD1. The output voltage VSUS may be presented as follow formula: VSUS=VC=I1×R1+VD1−VGS, wherein VGS is a voltage difference between the gate and source of the transistor T1. That is, a voltage level of the output voltage VSUS is smaller than a voltage level of the power source VDD. The oscillator 210 and the logical circuit 290 may operate in a low power consumption status. In additional, the clock signal CK1 may swing between the output voltage VSUS and the reference ground GND.

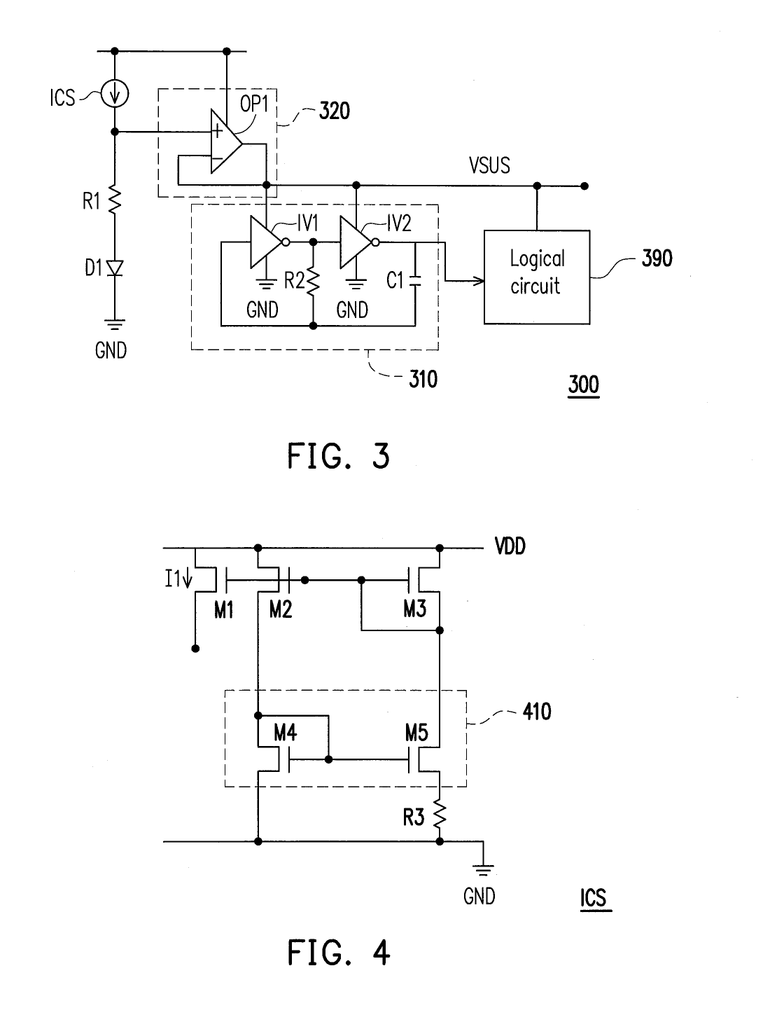

Referring to FIG. 3, FIG. 3 is a circuit diagram of a clock apparatus 300 according to another embodiment of the present invention. The clock apparatus 300 includes a current source ICS, a resistor R1, a diode D1, an amplifier 320 and an oscillator 310. The oscillator 310 is used to generate a clock signal CK1 to provide to the logical circuit 390. In this embodiment, the amplifier 320 is an operation amplifier OP1. The operation amplifier OP1 has a first input end, a second input end and an output end, the first input end of the operation amplifier OP1 is coupled to the first end of the resistor R1, the second input end of the operation amplifier OP1 is coupled to the output end of the operation amplifier OP1, and the output end of the operation amplifier OP1 generates the output voltage VSUS. That is, the operation amplifier OP1 is configured to a voltage follower, and the output voltage VSUS generated by the operation amplifier OP1 equals to the voltage VC on the first end of the resistor R1.

As describe above, the output voltage VSUS is used to provide an operation power to the oscillator 310 and logical circuit 390. A voltage level of the output voltage VSUS may be set by selecting the resistor R1, the current source ICS and the diode D1. Once the voltage level of the output voltage VSUS is low enough, the total power consumption of the oscillator 310 and the logical circuit 390 may be reduced.

Referring to FIG. 4, FIG. 4 is a circuit diagram of the current source ICS in FIGS. 1-3 of the embodiments of the present invention. The current source ICS includes transistors M1-M5 and resistor R3. The transistor M1 has a first end, a second end and a control end. The first end of the first transistor is coupled to the power source VDD, and the second end of the transistor M1 generates the current I1. The transistor M2 has a first end, a second end and a control end. The first end of the transistor M2 is coupled to the power source VDD, and the control end of the transistor M2 is coupled to the control end of the transistor M1. The transistor M3 has a first end, a second end and a control end. The first end of the transistor M3 is coupled to the power source VDD, the second and control ends of the transistor M3 are coupled to the control end of the transistor M2. The transistor M4 has a first end, a second end and a control end. The first and control ends of the transistor M4 are coupled to the second end of the transistor M2, the second end of the fourth transistor is coupled to the reference ground GND. The transistor M5 has a first end, a second end and a control end. The first end of the fifth transistor is coupled to the second end of the third transistor, and the control end of the fifth transistor is coupled to the control end of the fourth transistor. The resistor R2 is coupled between the second end of the transistor M5 and the reference ground GND.

The transistors M4 and M5 form a current mirror 410. A ratio of the current mirror 410 may be set by choosing a width-length ratio of the transistor M4 or the transistor M5. The ratio of the transistors M4 and M5 may also be set by choosing the width-length ratios of the transistors M4 and M5. Besides, a resistance of the resistor R3 may be selected by a designer. That is, by choosing the ratio of the current mirror 410 and the resistance of the resistor R3, the current I1 generated by the current source is independent to process variation and a voltage variation of the power source VDD. And the current I1 is in direct proportion to the environment temperature.

What is claimed is:

1. A clock apparatus, comprising:
a current source, providing a current, and the current having a first temperature coefficient;
a first resistor, having a first end coupled to the current source for receiving the current;
a diode, having an anode coupled to a second end of the first resistor, a cathode of the diode being coupled to a reference ground, the diode having a second temperature coefficient;
an amplifier, coupled to the first end of the first resistor and receiving a power source, the amplifier generating an output voltage according to the power source and a voltage on the first end of the first resistor; and
an oscillator, coupled to the amplifier for receiving the output voltage to be an operating power,
wherein, the first and second temperature coefficients are complementary.

2. The clock apparatus according to claim 1, wherein the first temperature coefficient is positive temperature coefficient, and the second temperature coefficient is negative temperature coefficient.

3. The clock apparatus according to claim 1, wherein the amplifier is a transistor, the transistor has a first end, a second end and a control end, the first end of the transistor receives the power source, the second end of the transistor generates the output voltage, and the control end of the transistor is coupled to the first end of the first resistor.

4. The clock apparatus according to claim 1, wherein the amplifier is an operation amplifier, the operation amplifier has a first input end, a second input end and an output end, the first input end is coupled to the first end of the first resistor, the second input end is coupled to the output end of the operation amplifier, and the output end of the operation amplifier generates the output voltage.

5. The clock apparatus according to claim 1, wherein the oscillator is a relaxation oscillator.

6. The clock apparatus according to claim 1, wherein the oscillator comprises:
a first inverter, receives the output voltage;
a second inverter, has an input end coupled to an output end of the first inverter, the second inverter receives the output voltage, and an output end of the second inverter generates a clock signal;
a second resistor, coupled between an input end of the first inverter and the output end of the first inverter in serial; and
a capacitor, coupled between the output end of the second inverter and the input end of the first inverter in serial.

7. The clock apparatus according to claim 1, wherein the clock signal is provided to a logical circuit with low power consumption.

8. The clock apparatus according to claim 1, wherein the current source comprises:
a first transistor, has a first end, a second end and a control end, the first end of the first transistor is coupled to the power source, the second end of the first transistor generates the current;
a second transistor, has a first end, a second end and a control end, the first end of the second transistor is coupled to the power source, the control end of the second transistor is coupled to the control end of the first transistor;
a third transistor, has a first end, a second end and a control end, the first end of the third transistor is coupled to the power source, the second and control ends of the third transistor are coupled to the control end of the second transistor;
a fourth transistor, has a first end, a second end and a control end, the first and control ends of the fourth transistor are coupled to the second end of the second transistor, the second end of the fourth transistor is coupled to the reference ground;
a fifth transistor, has a first end, a second end and a control end, the first end of the fifth transistor is coupled to the second end of the third transistor, the control end of the fifth transistor is coupled to the control end of the fourth transistor; and
a resistor, the resistor is coupled between the second end of the fifth transistor and the reference ground.
